(19) United States
(12) Patent Application Publication
(10) Pub. No.: US 2023/0012393 A1
(43) Pub. Date: Jan. 12, 2023

(54) USAGE-AWARE COMPRESSION FOR STREAMING DATA FROM A TEST AND MEASUREMENT INSTRUMENT

(71) Applicant: Tektronix, Inc., Beaverton, OR (US)

(72) Inventor: Keith D. Rule, Beaverton, OR (US)

(73) Assignee: Tektronix, Inc., Beaverton, OR (US)

(21) Appl. No.: 17/859,989

(22) Filed: Jul. 7, 2022

Related U.S. Application Data
(60) Provisional application No. 63/220,883, filed on Jul. 12, 2021.

(51) Int. Cl. G01R 31/319; G01R 31/317; G01R 31/302

(52) U.S. Cl. CPC G01R 31/31901; G01R 31/31912; G01R 31/31725; G01R 31/3025

(57) ABSTRACT

A test and measurement instrument includes one or more ports including at least one test port configured to couple to one or more devices under test, a user interface to receive one or more user inputs, an acquisition memory to store waveform data acquired from the one or more devices under test, one or more processors configured to execute code that causes the one or more processors to: receive an input through the user interface; determine one or more requested data types based on the input; transform the waveform data into compressed data containing only data elements corresponding to the one or more requested data types; and transmit the compressed data to a client. A method of providing usage-aware compressed data from a test and measurement instrument includes acquiring waveform data from one or more devices under test, receiving a user input through a user interface, determining one or more requested data types based on the user input, transforming the waveform data into compressed data containing only data elements corresponding to the one or more requested data types, and transmitting the compressed data to a client.

### CROSS-REFERENCE TO RELATED APPLICATIONS

This disclosure claims benefit of U.S. Provisional Application No. 63/220,883, titled “USAGE-AWARE COMPRESSION FOR STREAMING DATA FROM A TEST AND MEASUREMENT INSTRUMENT,” filed on Jul. 12, 2021, the disclosure of which is incorporated herein by reference in its entirety.

### TECHNICAL FIELD

This disclosure relates to test and measurement instruments, and more particularly to compression techniques for use in streaming acquired data from a test and measurement instrument.

### BACKGROUND

Test and measurement instruments, such as oscilloscopes, use high-speed digitizing and acquisition systems to acquire large quantities of measured data. This acquired data is typically stored in local storage on the test and measurement instrument. However, users often want the ability to move and analyze this acquired data on other remote instruments, computing devices, or systems. Conventional techniques for moving acquired data from a test and measurement instrument are slow and cumbersome. Significantly reducing time to move instrument data across a network would provide incredible benefits to users. Reducing the amount of data provides one way to accomplish this.

Existing high compression techniques are lossy, meaning the compression process loses some data content. Many applications can accept this because the data has a single application. For example, MP3 encoders implicitly know that the target usage is playing audio. Therefore, the tradeoff for compression is well understood. However, waveform data from test and measurement instruments such as oscilloscopes and digitizers has many possible usages, which makes using a general lossy, high compression technique difficult or impossible.

### BRIEF DESCRIPTION OF THE DRAWINGS

FIG. 1 shows an embodiment of a test and measurement instrument.

FIG. 2 shows a diagram of examples of test instrument data compression.

FIG. 3 shows a flowchart of an embodiment of a method of usage-aware data compression.

### DETAILED DESCRIPTION

Embodiments of the disclosure include a method of performing lossy data compression with test and measurement instruments such as scopes and digitizers. The user provides an input that makes the instrument aware, either implicitly or explicitly, of the intended use of the data so that it can remove unnecessary data elements. This provides high compression to the data. The instrument can provide further reduction of the data using existing lossless compression techniques on the transformed data.

The large variety of applications of waveform data makes it difficult to use high-compression data techniques for waveform data. The instruments, such as real-time oscilloscopes, sampling oscilloscopes, and digitizers, have no way to know what elements of the waveform are unnecessary for the client. Consequently, no general high-compression techniques exist for waveform data.

In some embodiments of the disclosed technology, the client provides information to the instrument to define the data usage. This information can result from the user defining targeted usage, like Display or Timing Measurements. This discussion will refer to this as implicit usage information, as the instrument can determine suitable compression based upon the application. Explicit usage information may result from the user requesting specific data types, rather than the raw waveform. Receiving this information at the instrument allows the instrument to perform lossy data reduction while keeping the required info.

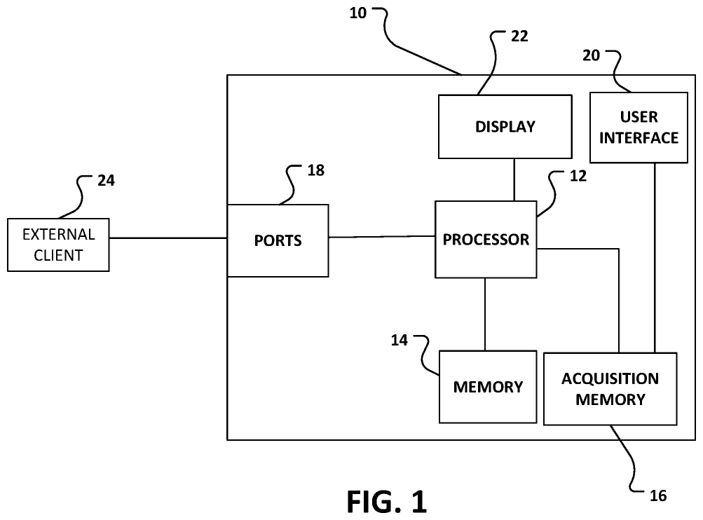

FIG. 1 shows an embodiment of such a test and measurement instrument. The embodiments here will generally include test and measurement instruments, such as oscilloscopes, digital multi-meters, source measurement units, etc. While some of these instruments may perform one or the other of testing and measuring, the term “test and measurement instrument” applies to both or any of these instruments.

In the discussion, the term “client” refers to any device, computing or otherwise, that requests or receives data from the test and measurement instrument. A client may comprise another test and measurement instrument, a computing device, or a file memory, as some examples. The test and measurement instrument may move the data across a network to an external client. The test and measurement instrument may also have internal clients, meaning devices within the test and measurement instrument that receives compressed data. This may include such items as a display or a memory. Generally, the benefits of compression become realized mostly in sending data across a communication link, such as a network, wired or wireless, for remote or near-field communications.

FIG. 1 shows an embodiment of a test and measurement instrument, referred to here as an instrument, which provides lossy compressed data to a client. As discussed above, the client may actually reside on the instrument, such as a display or internal memory. The benefits may include increased speed or reduced file size, as examples. One should note that the discussion might refer to the internal memory 14, which may comprise an internal client of the instrument, and an acquisition memory 16. These may comprise separate memory locations, partitions, or devices, or they may all comprise one memory. Any or all of these memories may reside on other devices. If the file memory to which the instrument may transmit the compressed data resides outside the test and measurement instrument, it would be an external client.

External clients may include other test and measurement instruments and other computing devices that connect to the test and measurement instrument through a communication port, either wired or wireless. The instrument 10 has one or more processors 12 and a memory 14. The memory 14 may store user information, user inputs, data, the instructions for the processor to execute that cause the instrument to operate, and the repository. The one or more processors are configured to execute code from the memory to cause the processors to perform the various tasks on the instrument. The instrument 10 communicates with external clients 24 through the ports 18.

User inputs from the user interface 20 may include knobs, buttons, touch-screens, connectors and connections related to the testing probes or other types of testing and/or measurement accessories used in the instrument's operation. An acquisition memory 16 will store the data received through the ports from devices under test, with the user inputs used to guide the acquisition of data. The user inputs may connect to the acquisition memory 16 and the acquisition memory 16 may connect to the processor 12. The instrument may also contain a user interface that allows the user to interact with the instrument. The combination of the user inputs through 20 and the display 22 represents an example of a user interface.

The instrument can produce several compressible data types in response to data usage information, however gathered. The compressible data types include edges for timing/bus related actions, where the user only has interest in signal edges, or the intervals in a waveform where the signals change state. Another timing-based compression may involve time ranges, such as a particular interval or intervals, such as zooming the display in on a particular interval, or information related to a set of particular intervals. Examples of sets of particular intervals may involve only sending intervals that show data bursts, or intervals that include a matching pattern.

Another compressible data type may comprise compressing bit-streams with timing information to allow for decoding. Test and measurement instruments typically have display screens that have a lower resolution that the available stream of data samples. This means that the data stream can undergo decimation, selective removal of samples to meet the resolution of the display. Another display data type comprises displaying data in two-dimensional (2D) histograms, allowing the instrument to send only enough data to construct the histograms, and not every sample included. The instrument may use these and other types of data compression in combination, such as time ranges of edges. One should note that these only comprise examples of different types of compressible data and are not intended to be exhaustive, nor should any such assumption be implied.

These and a few variants cover most of the data types needed. Each of these data types provides a significant reduction from the underlying real-time waveform. This, optionally combined with standard lossless compression techniques, will significantly reduce data size, which will reduce network transmission time. In the below discussion, the term data type refers to the type of data being requested, such as edges, the entire waveform, histograms, etc. The term data element refers to the elements that make up the compressed data. As this is lossy compression, this comprises the data remaining after removal of the unneeded data.

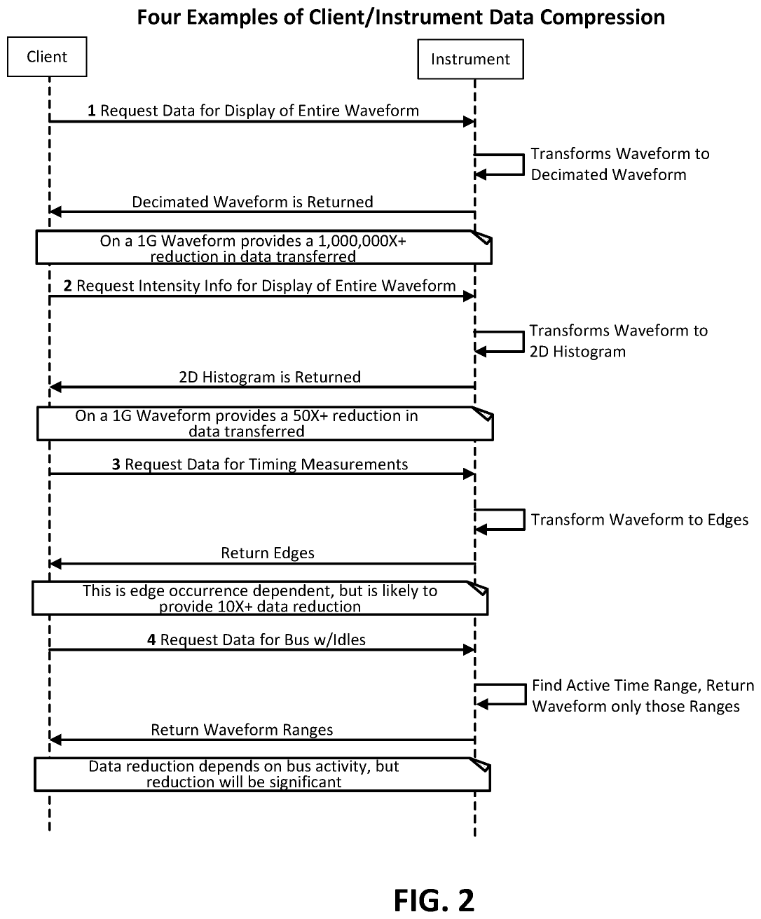

FIG. 2 shows a graphical representation of some examples of compression and estimates of the data transfer reduction. A first example comprises requesting display of an entire waveform. The test and measurement instrument, or instrument, decimates the waveform, since the display will not have enough resolution to display the entire waveform. A viewer would not notice the difference if a lower number than all of the data samples collected for a given waveform was displayed. On a 1 Gigasample waveform, reducing the data by 1,000,000 times still results in 1000 samples for display. For display, this results in a compression of 8,000,000,000 bytes to 8000 bytes. The below estimates of data reduction are based upon a 1 G waveform.

Another type of data reduction occurs if the requested data type comprises a 2D histogram. The instrument transforms the waveform data into the 2D histogram. The data transmitted will consist of a very few number of data elements relative to the data of the entire waveform. For a typical sampling scope, histograms are 752 h×1000 w and each element is 8 bytes wide, so a 2D histogram for a sampling scope is 8 million bytes. The compression depends upon the size of the original data. In one embodiment, the process aligns 1 bit or 1 symbol into a 2D histogram, the overlays all the bits or symbols to create an eye diagram. Ten million bits, or unit intervals, having 10 samples/UI results in 100 million samples. Each sample is 4 bytes, resulting in 400 million bytes. The compression takes that total from 400,000,000 bytes to 8,000,000 bytes, for a 50× compression. This varies for different types of scopes and other test and measurement instruments. The above discussion only provides an example. Real-time scopes typically have smaller histograms, so they would have a higher compression rate.

Another type of data would be data for timing measurements, such as edges of the waveform(s), discussed above. The instrument transforms the waveform data to include only the edge data. The data reduction may vary, as the edges do not appear the same across different waveforms, but providing only the edge data would result in an estimated 10 times reduction of data transferred. Another type of data involves bus data, such as data bursts and idles. Similar to edge data, this depends upon the bus activity, as the instrument transforms the data by sending only the waveform data for bus active times. By only sending the bus activity designated, it results in a significant reduction of data transferred.

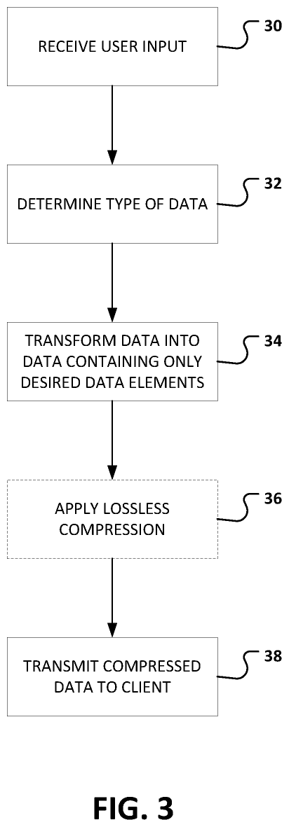

FIG. 3 shows a flowchart of an embodiment of this process. At 30, the instrument receives a user input through the user interface or a port if the user input comes across the network. The user input may include explicit or implicit information about the data type(s) requested, such as from the intended usage of the data. For example, the input may define targeted usage, such as display or timing measurements, from which the one or more processors would determine the data elements to return. Alternatively, the input could explicitly identify the data desired by data type(s). In either case, the instrument determines the type of data at 32. One should note that while the discussion refers to a data type, for ease of understanding, some embodiments would involve more than one type of data, with compressed data having different data elements.

Upon determination of the data type, the instrument will transform the data at 34 by removing unneeded data, such as removing all but the edge data, or processing the data, such as producing a histogram to produce the compressed data. As discussed above, this process comprises lossy compression because data is purposefully lost. After the data elements have been prepared, the instrument could apply lossless compression optionally at 36 to allow for a further reduction of the data transfer. Lossless data compression results in no loss of data. The original data can be recovered exactly from the compressed data after a decompression cycle, sometimes referred to also as decoding. Examples of lossless compression includes statistical compressors such as Huffman encoding, and Shannon-Fano compression, and dictionary-based compressors such as LZ77 and LZ78 (Lempel-Ziv). Once compressed, by lossy compression alone, or from a combination of lossy and lossless compression, the instrument transmits the compressed data to the client at 38, which may include saving the compressed data to a file.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

### EXAMPLES

Illustrative examples of the disclosed technologies are provided below. An embodiment of the technologies may include one or more, and any combination of, the examples described below.

Example 1 is a test and measurement instrument, comprising: one or more ports including at least one test port configured to couple to one or more devices under test; a user interface to receive one or more user inputs; an acquisition memory to store waveform data acquired from the one or more devices under test; and one or more processors configured to execute code that causes the one or more processors to: receive an input through the user interface; determine one or more requested data types based on the input; transform the waveform data into compressed data containing only data elements corresponding to the one or more requested data types; and transmit the compressed data to a client.

Example 2 is the test and measurement instrument of Example 1, wherein the one or more ports include at least one output port to connect to an external client.

Example 3 is the test and measurement instrument of Example 2, wherein the at least one output port comprises at least one of a wired port or a wireless port.

Example 4 is the test and measurement instrument of any of Examples 1 through 3, wherein the user interface comprises a display.

Example 5 is the test and measurement instrument of any of Examples 1 through 4, wherein the client is an internal client and comprises at least one of a display and a file memory.

Example 6 is the test and measurement instrument of Example 5, wherein the file memory comprises at least one of the acquisition memory, a memory internal to the test and measurement instrument, and a memory external to the test and measurement instrument.

Example 7 is the test and measurement instrument of any of Examples 1 through 6, wherein the input comprises an explicit selection of the type of data, and the code to cause the one or more processors to determine one or more requested data types comprises code to cause the one or more processors to receive the type of data.

Example 8 is the test and measurement instrument of any of Examples 1 through 7, wherein the input comprises an implicit selection requesting particular test data, and the code to cause the one or more processors to determine one or more requested data types comprises code to cause the one or more processors to determine the one or more requested data types based on the particular test data.

Example 9 is the test and measurement instrument of any of Examples 1 through 8, wherein the code to cause the one or more processors to transform the data further comprises code to cause the one or more processors to apply lossless compression to the data elements.

Example 10 is the test and measurement instrument of any of Examples 1 through 9, wherein the client comprises an external computing device, wherein the user interface comprises a user interface of the external computing device, and wherein the code to cause the one or more processors to transmit the compressed data to the client comprises code to cause the one or more processors to transmit the compressed data to the external computing device over a network.

Example 11 is a method of providing usage-aware compressed data from a test and measurement instrument, comprising: acquiring waveform data from one or more devices under test; receiving a user input through a user interface; determining one or more requested data types based on the user input; transforming the waveform data into compressed data containing only data elements corresponding to the one or more requested data types; and transmitting the compressed data to a client.

Example 12 is the method of Example 11, wherein receiving the user input comprises receiving an explicit selection of one or more types of data, and determining one or more requested data types comprises using the explicit selection of the one or more types of data.

Example 13 is the method of either of Examples 11 or 12, wherein receiving the user input comprises receiving an implicit selection requesting particular test data, and determining one or more requested data types comprises determining the one or more requested data types based on the particular test data.

Example 14 is the method of any of Examples 11 through 13, wherein transmitting the compressed data to the client comprises transmitting the compressed data to an external client through one of a wired or wireless port.

Example 15 is the method of any of Examples 11 through 14, wherein transmitting the compressed data to the client comprises transmitting the compressed data to an internal client.

Example 16 is the method of any of Examples 11 through 15, wherein the one or more requested data types comprises one or more of data to display an entire waveform, intensity information for the entire waveform, data of timing measurements, data of bus operations, waveform ranges, and combinations of data types.

Example 17 is the method of any of Examples 11 through 16, wherein transforming the waveform data into compressed data comprises transforming the waveform data into one or more of data elements for a decimated waveform, a two-dimensional histogram, data of edges, data of bus operations, data of only selected waveform ranges, and combinations of data elements.

Example 18 is the method of any of Examples 11 through 17, further comprising applying lossless compression to the compressed data prior to transmitting the compressed data to the client.

Example 19 is the method of any of Examples 11 through 18, wherein the client comprises an external computing device, wherein the user interface comprises a user interface of the external computing device, and wherein transmitting the compressed data to the client comprises transmitting the compressed data to the external computing device over a network.

Although specific aspects of the disclosure have been illustrated and described for purposes of illustration, it will be understood that various modifications may be made without departing from the spirit and scope of the disclosure. Accordingly, the disclosure should not be limited except as by the appended claims.

We claim:

1. A test and measurement instrument, comprising:
one or more ports including at least one test port configured to couple to one or more devices under test;
a user interface to receive one or more user inputs;
an acquisition memory to store waveform data acquired from the one or more devices under test; and
one or more processors configured to execute code that causes the one or more processors to:
receive an input through the user interface;
determine one or more requested data types based on the input;
transform the waveform data into compressed data containing only data elements corresponding to the one or more requested data types ; and
transmit the compressed data to a client.

2. The test and measurement instrument as claimed in claim 1, wherein the one or more ports include at least one output port to connect to an external client.

3. The test and measurement instrument as claimed in claim 2, wherein the at least one output port comprises at least one of a wired port or a wireless port.

4. The test and measurement instrument as claimed in claim 1, wherein the user interface comprises a display.

5. The test and measurement instrument as claimed in claim 1, wherein the client is an internal client and comprises at least one of a display and a file memory.

6. The test and measurement instrument as claimed in claim 5, wherein the file memory comprises at least one of the acquisition memory, a memory internal to the test and measurement instrument, and a memory external to the test and measurement instrument.

7. The test and measurement instrument as claimed in claim 1, wherein the input comprises an explicit selection of the type of data, and the code to cause the one or more processors to determine one or more requested data types comprises code to cause the one or more processors to receive the type of data.

8. The test and measurement instrument as claimed in claim 1, wherein the input comprises an implicit selection requesting particular test data, and the code to cause the one or more processors to determine one or more requested data types comprises code to cause the one or more processors to determine the one or more requested data types based on the particular test data.

9. The test and measurement instrument as claimed in claim 1, wherein the code to cause the one or more processors to transform the data further comprises code to cause the one or more processors to apply lossless compression to the data elements.

10. The test and measurement instrument as claimed in claim 1, wherein the client comprises an external computing device, wherein the user interface comprises a user interface of the external computing device, and wherein the code to cause the one or more processors to transmit the compressed data to the client comprises code to cause the one or more processors to transmit the compressed data to the external computing device over a network.

11. A method of providing usage-aware compressed data from a test and measurement instrument, comprising:
acquiring waveform data from one or more devices under test;
receiving a user input through a user interface;
determining one or more requested data types based on the user input;
transforming the waveform data into compressed data containing only data elements corresponding to the one or more requested data types; and
transmitting the compressed data to a client.

12. The method as claimed in claim 11, wherein receiving the user input comprises receiving an explicit selection of one or more types of data, and determining one or more requested data types comprises using the explicit selection of the one or more types of data.

13. The method as claimed in claim 11, wherein receiving the user input comprises receiving an implicit selection requesting particular test data, and determining one or more requested data types comprises determining the one or more requested data types based on the particular test data.

14. The method as claimed in claim 11, wherein transmitting the compressed data to the client comprises transmitting the compressed data to an external client through one of a wired or wireless port.

15. The method as claimed in claim 11, wherein transmitting the compressed data to the client comprises transmitting the compressed data to an internal client.

16. The method as claimed in claim 11, wherein the one or more requested data types comprises one or more of data to display an entire waveform, intensity information for the entire waveform, data of timing measurements, data of bus operations, waveform ranges, and combinations of data types.

17. The method as claimed in claim 11, wherein transforming the waveform data into compressed data comprises transforming the waveform data into one or more of data elements for a decimated waveform, a two-dimensional histogram, data of edges, data of bus operations, data of only selected waveform ranges, and combinations of data elements.

18. The method as claimed in claim 11, further comprising applying lossless compression to the compressed data prior to transmitting the compressed data to the client.

19. The method as claimed in claim 11, wherein the client comprises an external computing device, wherein the user interface comprises a user interface of the external computing device, and wherein transmitting the compressed data to the client comprises transmitting the compressed data to the external computing device over a network.
